(19) United States
(12) Patent Application Publication
(10) Pub. No.: US 2025/0350305 A1
(43) Pub. Date: Nov. 13, 2025

(54) SPLIT MAIN AND PREDISTORTION SIGNAL PATHS WITH SEPARATE DIGITAL-TO-ANALOG CONVERTERS FOR SUPPORTING DIGITAL PREDISTORTION IN TRANSMITTERS

(71) Applicant: QUALCOMM Incorporated, San Diego, CA (US)

(72) Inventors: Shahin MEHDIZAD TALEIE, San Diego, CA (US); Beomsoo PARK, San Diego, CA (US); Peter SHAH, San Diego, CA (US); Dongwon SEO, San Diego, CA (US); Sang-June PARK, San Diego, CA (US); Ariel Yaakov SAGI, Haifa (IL); Haibo FEI, San Diego, CA (US)

(21) Appl. No.: 18/868,656

(22) PCT Filed: Jun. 28, 2023
(86) PCT No.: PCT/US2023/069298

§ 371 Date: Nov. 22, 2024

(30) Foreign Application Priority Data
Jul. 24, 2022 (IL) 294994

(51) Int. Cl. H04B 1/04; H03F 1/32; H03F 3/24; H03M 1/66

(52) U.S. Cl. CPC H04B 1/0475; H03F 1/3241; H03F 3/245; H03F 2200/451; H03M 1/66

(57) ABSTRACT

Methods and apparatus for wireless communication using a transmitter capable of digital predistortion (DPD) and having a main signal path separated from a predistortion signal path, each path including a digital-to-analog converter (DAC). An example apparatus generally includes a main signal path comprising a first DAC, a power amplifier, and a combiner, the combiner being disposed in the main signal path between an output of the first DAC and an input of the power amplifier. The apparatus also includes a predistortion signal path comprising a second DAC, wherein the combiner is configured to combine a predistortion signal in the predistortion signal path with a main signal in the main signal path.

### CROSS-REFERENCE TO RELATED APPLICATION(S)

This application claims priority to Israel Patent Application No. 294994, filed Jul. 24, 2022, the entire contents of which are incorporated herein by reference.

### TECHNICAL FIELD

Certain aspects of the present disclosure generally relate to electronic circuits and, more particularly, to wireless transmission devices with digital predistortion (DPD) processing capabilities.

### BACKGROUND

Wireless communication devices are widely deployed to provide various communication services such as telephony, video, data, messaging, broadcasts, and so on. Such wireless communication devices may transmit and/or receive radio frequency (RF) signals via any of various suitable radio access technologies (RATs) including, but not limited to, Fifth Generation (5G) New Radio (NR), Long Term Evolution (LTE), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., WiFi), and the like.

A wireless communication network may include a number of base stations that can support communication for a number of mobile stations. A mobile station (MS) may communicate with a base station (BS) via a downlink and an uplink. The downlink (or forward link) refers to the communication link from the base station to the mobile station, and the uplink (or reverse link) refers to the communication link from the mobile station to the base station. A base station may transmit data and control information on the downlink to a mobile station and/or may receive data and control information on the uplink from the mobile station. The base station and/or mobile station may include a transmission digital-to-analog converter (TxDAC), which may be used, for example, to convert a digital signal to an analog signal for signal processing (e.g., filtering, upconverting, and amplifying) before transmission by one or more antennas.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages that include reduced power and area consumption and relaxed thermal design specifications for the digital-to-analog conversion architecture to support digital predistortion (DPD) in a transmitter, which may also result in reduced overall cost.

Certain aspects of the present disclosure generally relate to a transmitter with DPD capabilities, in which a main signal path and a predistortion signal path have been separated to route a main signal through a main digital-to-analog converter (DAC) and to route a predistortion signal through a predistortion DAC.

Certain aspects of the present disclosure provide an apparatus for wireless communication. The apparatus generally includes a main signal path comprising a first digital-to-analog converter (DAC), a power amplifier, and a combiner. The combiner is disposed in the main signal path between an output of the first DAC and an input of the power amplifier. The apparatus also generally includes a predistortion signal path comprising a second DAC, wherein the combiner is configured to combine a predistortion signal in the predistortion signal path with a main signal in the main signal path.

Certain aspects of the present disclosure provide a method of wireless communication. The method generally includes converting a digital main signal into an analog main signal, via a first DAC in a main signal path; converting a digital predistortion signal into an analog predistortion signal, via a second DAC in a predistortion signal path; combining, via a combiner disposed in the main signal path, the analog main signal or a processed version of the analog main signal with the analog predistortion signal or a processed version of the analog predistortion signal, to create an analog combined signal; and amplifying, via a power amplifier disposed in the main signal path, the analog combined signal or a processed version of the analog combined signal.

Certain aspects of the present disclosure provide an apparatus for wireless communication. The apparatus generally includes first means for converting a digital main signal into an analog main signal, the first means for converting being disposed in a main signal path; second means for converting a digital predistortion signal into an analog predistortion signal, the second means for converting being disposed in a predistortion signal path; means for combining the analog main signal or a processed version of the analog main signal with the analog predistortion signal or a processed version of the analog predistortion signal, to create an analog combined signal, the means for combining being disposed in the main signal path; and means for amplifying the analog combined signal or a processed version of the analog combined signal, the means for amplifying being disposed in the main signal path.

Certain aspects of the present disclosure provide a method of wireless communication. The method generally includes converting a digital main signal into an analog main signal, via a first DAC in a main signal path; converting a digital predistortion signal into an analog predistortion signal, via a second DAC in a predistortion signal path; combining, via a combiner disposed in the main signal path, the analog main signal with the analog predistortion signal to create an analog combined signal; processing the analog combined signal; and amplifying, via a power amplifier disposed in the main signal path, the processed analog combined signal.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example wireless communications network, in which aspects of the present disclosure may be practiced.

FIG. 2 is a block diagram conceptually illustrating a design of an example base station (BS) and user equipment (UE), in which aspects of the present disclosure may be practiced.

FIG. 3 is a block diagram of an example radio frequency (RF) transceiver, in which aspects of the present disclosure may be practiced.

FIG. 4 is a block diagram of an example transmitter in which a predistortion signal is combined with a main signal before a digital-to-analog converter (DAC).

FIG. 5 is block diagram of an example transmitter with a predistortion signal path separate from a main signal path, each having a DAC, and in which the predistortion signal is combined with a main signal after the DACs, in accordance with certain aspects of the present disclosure.

FIG. 6A is a block diagram of an example implementation of the transmitter of FIG. 5, in accordance with certain aspects of the present disclosure.

FIG. 6B is a diagram illustrating a predistortion signal and a main signal as a combined signal and as separate signals, in accordance with certain aspects of the present disclosure.

FIG. 6C is a block diagram of another example implementation of the transmitter of FIG. 5, in accordance with certain aspects of the present disclosure.

FIG. 7 is a flow diagram of example operations for wireless communication, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure relate to techniques and apparatus for wireless communication, such as a transmission device with digital predistortion (DPD) capabilities. The transmission device may have separate processing paths for a main signal and a predistortion signal. That is, separate digital-to-analog converters (DACs) (and potentially other separate components) may be used to process the main signal and the predistortion signal. Accordingly, operating characteristics of the DACs (and other components) may be designed so that the circuit may process the signals more efficiently (e.g., with lower power) compared to a single signal path with one DAC processing a combination of the signals.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Wireless System

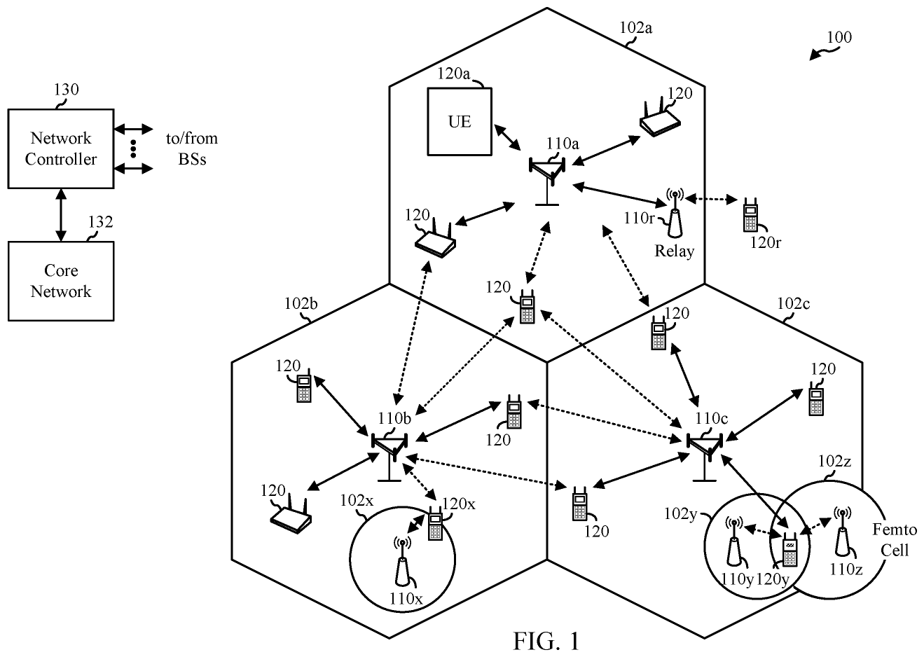

FIG. 1 illustrates an example wireless communications network 100, in which aspects of the present disclosure may be practiced. For example, the wireless communications network 100 may be a New Radio (NR) system (e.g., a Fifth Generation (5G) NR network), an Evolved Universal Terrestrial Radio Access (E-UTRA) system (e.g., a Fourth Generation (4G) network), a Universal Mobile Telecommunications System (UMTS) (e.g., a Second Generation/Third Generation (2G/3G) network), or a code division multiple access (CDMA) system (e.g., a 2G/3G network), or may be configured for communications according to an IEEE standard such as one or more of the 802.11 standards, etc.

As illustrated in FIG. 1, the wireless communications network 100 may include a number of base stations (BSs) 110a-z (each also individually referred to herein as “BS 110” or collectively as “BSs 110”) and other network entities. A BS may also be referred to as an access point (AP), an evolved Node B (eNodeB or eNB), a next generation Node B (gNodeB or gNB), or some other terminology.

A BS 110 may provide communication coverage for a particular geographic area, sometimes referred to as a “cell,” which may be stationary or may move according to the location of a mobile BS 110. In some examples, the BSs 110 may be interconnected to one another and/or to one or more other BSs or network nodes (not shown) in wireless communications network 100 through various types of backhaul interfaces (e.g., a direct physical connection, a wireless connection, a virtual network, or the like) using any suitable transport network. In the example shown in FIG. 1, the BSs 110a, 110b, and 110c may be macro BSs for the macro cells 102a, 102b, and 102c, respectively. The BS 110x may be a pico BS for a pico cell 102x. The BSs 110y and 110z may be femto BSs for the femto cells 102y and 102z, respectively. A BS may support one or multiple cells.

The BSs 110 communicate with one or more user equipments (UEs) 120a-y (each also individually referred to herein as “UE 120” or collectively as “UEs 120”) in the wireless communications network 100. A UE may be fixed or mobile and may also be referred to as a user terminal (UT), a mobile station (MS), an access terminal, a station (STA), a client, a wireless device, a mobile device, or some other terminology. A user terminal may be a wireless device, such as a cellular phone, a smartphone, a personal digital assistant (PDA), a handheld device, a wearable device, a wireless modem, a laptop computer, a tablet, a personal computer, etc.

The BSs 110 are considered transmitting entities for the downlink and receiving entities for the uplink. The UEs 120 are considered transmitting entities for the uplink and receiving entities for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink. Nᵤₚ UEs may be selected for simultaneous transmission on the uplink, N_{dn} UEs may be selected for simultaneous transmission on the downlink. Nᵤₚ may or may not be equal to N_{dn}, and Nᵤₚ and N_{dn} may be static values or can change for each scheduling interval. Beam-steering or some other spatial processing technique may be used at the BSs 110 and/or UEs 120.

The UEs 120 (e.g., 120x, 120y, etc.) may be dispersed throughout the wireless communications network 100, and each UE 120 may be stationary or mobile. The wireless communications network 100 may also include relay stations (e.g., relay station 110r), also referred to as relays or the like, that receive a transmission of data and/or other information from an upstream station (e.g., a BS 110a or a UE 120r) and send a transmission of the data and/or other information to a downstream station (e.g., a UE 120 or a BS 110), or that relays transmissions between UEs 120, to facilitate communication between devices.

The BSs 110 may communicate with one or more UEs 120 at any given moment on the downlink and uplink. The downlink (i.e., forward link) is the communication link from the BSs 110 to the UEs 120, and the uplink (i.e., reverse link) is the communication link from the UEs 120 to the BSs 110. A UE 120 may also communicate peer-to-peer with another UE 120.

The wireless communications network 100 may use multiple transmit and multiple receive antennas for data transmission on the downlink and uplink. BSs 110 may be equipped with a number Nₐₚ of antennas to achieve transmit diversity for downlink transmissions and/or receive diversity for uplink transmissions. A set Nᵤ of UEs 120 may receive downlink transmissions and transmit uplink transmissions. Each UE 120 may transmit user-specific data to and/or receives user-specific data from the BSs 110. In general, each UE 120 may be equipped with one or multiple antennas. The Nᵤ UEs 120 can have the same or different number of antennas.

The wireless communications network 100 may be a time division duplex (TDD) system or a frequency division duplex (FDD) system. For a TDD system, the downlink and uplink share the same frequency band. For an FDD system, the downlink and uplink use different frequency bands. The wireless communications network 100 may also utilize a single carrier or multiple carriers for transmission. Each UE 120 may be equipped with a single antenna (e.g., to keep costs down) or multiple antennas (e.g., where the additional cost can be supported).

A network controller 130 (also sometimes referred to as a “system controller”) may be in communication with a set of BSs 110 and provide coordination and control for these BSs 110 (e.g., via a backhaul). In certain cases (e.g., in a 5G NR system), the network controller 130 may include a centralized unit (CU) and/or a distributed unit (DU). In certain aspects, the network controller 130 may be in communication with a core network 132 (e.g., a 5G Core Network (5GC)), which provides various network functions such as Access and Mobility Management, Session Management, User Plane Function, Policy Control Function, Authentication Server Function, Unified Data Management, Application Function, Network Exposure Function, Network Repository Function, Network Slice Selection Function, etc.

NR may utilize orthogonal frequency division multiplexing (OFDM) with a cyclic prefix (CP) on the uplink and downlink. NR may support half-duplex operation using time division duplexing (TDD). OFDM and single-carrier frequency division multiplexing (SC-FDM) partition the system bandwidth into multiple orthogonal subcarriers, which are also commonly referred to as tones, bins, etc. Each subcarrier may be modulated with data. Modulation symbols may be sent in the frequency domain with OFDM and in the time domain with SC-FDM. The spacing between adjacent subcarriers may be fixed, and the total number of subcarriers may be dependent on the system bandwidth. The system bandwidth may also be partitioned into subbands. For example, a subband may cover multiple resource blocks (RBs).

In certain aspects of the present disclosure, the BSs 110 and/or the UEs 120 may include a transmission device with a main signal path with a main digital-to-analog converter (DAC) and a predistortion signal path with a predistortion DAC, where a main signal in the main signal path after the main DAC may be combined with a predistortion signal in the predistortion path after the predistortion DAC, as described in more detail herein.

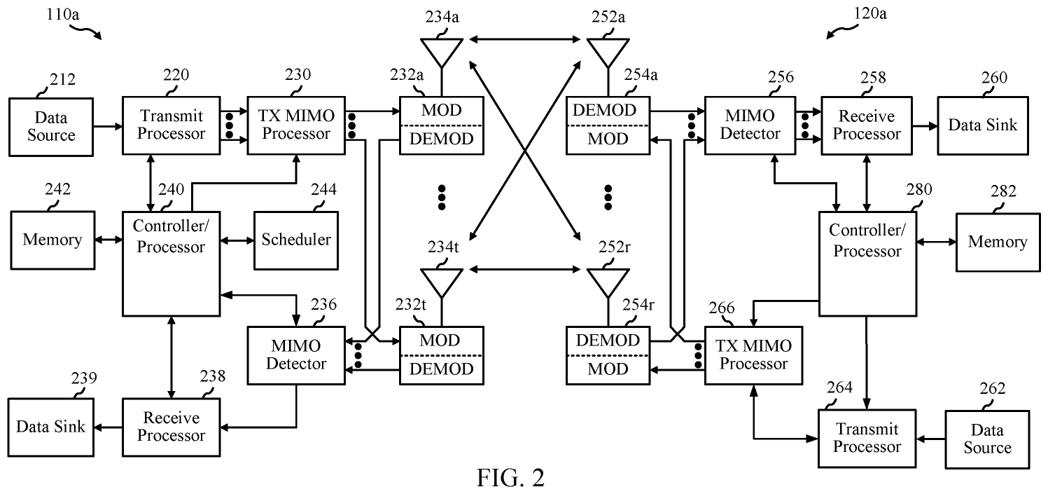

FIG. 2 illustrates example components of BS 110a and UE 120a (e.g., from the wireless communications network 100 of FIG. 1), in which aspects of the present disclosure may be implemented.

On the downlink, at the BS 110a, a transmit processor 220 may receive data from a data source 212, control information from a controller/processor 240, and/or possibly other data (e.g., from a scheduler 244). The various types of data may be sent on different transport channels. For example, the control information may be designated for the physical broadcast channel (PBCH), physical control format indicator channel (PCFICH), physical hybrid automatic repeat request (HARQ) indicator channel (PHICH), physical downlink control channel (PDCCH), group common PDCCH (GC PDCCH), etc. The data may be designated for the physical downlink shared channel (PDSCH), etc. A medium access control (MAC)-control element (MAC-CE) is a MAC layer communication structure that may be used for control command exchange between wireless nodes. The MAC-CE may be carried in a shared channel such as a PDSCH, a physical uplink shared channel (PUSCH), or a physical sidelink shared channel (PSSCH).

The processor 220 may process (e.g., encode and symbol map) the data and control information to obtain data symbols and control symbols, respectively. The transmit processor 220 may also generate reference symbols, such as for the primary synchronization signal (PSS), secondary synchronization signal (SSS), PBCH demodulation reference signal (DMRS), and channel state information reference signal (CSI-RS).

A transmit (TX) multiple-input, multiple-output (MIMO) processor 230 may perform spatial processing (e.g., precoding) on the data symbols, the control symbols, and/or the reference symbols, if applicable, and may provide output symbol streams to the modulators (MODs) in transceivers 232a-232t. Each modulator in transceivers 232a-232t may process a respective output symbol stream (e.g., for orthogonal frequency division multiplexing (OFDM), etc.) to obtain an output sample stream. Each of the transceivers 232a-232t may further process (e.g., convert to analog, amplify, filter, and upconvert) the output sample stream to obtain a downlink signal. Downlink signals from the transceivers 232a-232t may be transmitted via the antennas 234a-234t, respectively.

At the UE 120a, the antennas 252a-252r may receive the downlink signals from the BS 110a and may provide received signals to the transceivers 254a-254r, respectively. The transceivers 254a-254r may condition (e.g., filter, amplify, downconvert, and digitize) a respective received signal to obtain input samples. Each demodulator (DEMOD) in the transceivers 232a-232t may further process the input samples (e.g., for OFDM, etc.) to obtain received symbols. A MIMO detector 256 may obtain received symbols from all the demodulators in transceivers 254a-254r, perform MIMO detection on the received symbols if applicable, and provide detected symbols. A receive processor 258 may process (e.g., demodulate, deinterleave, and decode) the detected symbols, provide decoded data for the UE 120a to a data sink 260, and provide decoded control information to a controller/processor 280.

On the uplink, at UE 120a, a transmit processor 264 may receive and process data (e.g., for the physical uplink shared channel (PUSCH)) from a data source 262 and control information (e.g., for the physical uplink control channel (PUCCH)) from the controller/processor 280. The transmit processor 264 may also generate reference symbols for a reference signal (e.g., the sounding reference signal (SRS)). The symbols from the transmit processor 264 may be precoded by a TX MIMO processor 266 if applicable, further processed by the modulators (MODs) in transceivers 254a-254r (e.g., for single-carrier frequency division multiplexing (SC-FDM), etc.), and transmitted to the BS 110a. At the BS 110a, the uplink signals from the UE 120a may be received by the antennas 234, processed by the demodulators in transceivers 232a-232t, detected by a MIMO detector 236 if applicable, and further processed by a receive processor 238 to obtain decoded data and control information sent by the UE 120a. The receive processor 238 may provide the decoded data to a data sink 239 and the decoded control information to the controller/processor 240.

The memories 242 and 282 may store data and program codes for BS 110a and UE 120a, respectively. The memories 242 and 282 may also interface with the controllers/processors 240 and 280, respectively. A scheduler 244 may schedule UEs for data transmission on the downlink and/or uplink.

Antennas 252, processors 258, 264, 266, and/or controller/processor 280 of the UE 120a and/or antennas 234, processors 220, 230, 238, and/or controller/processor 240 of the BS 110a may be used to perform the various techniques and methods described herein.

In certain aspects of the present disclosure, the transceivers 232 and/or the transceivers 254 may include a main signal path with a main digital-to-analog converter (DAC) and a predistortion signal path with a predistortion DAC, where a main signal in the main signal path after the main DAC may be combined with a predistortion signal in the predistortion path after the predistortion DAC, as described in more detail herein.

### Example RF Transceiver

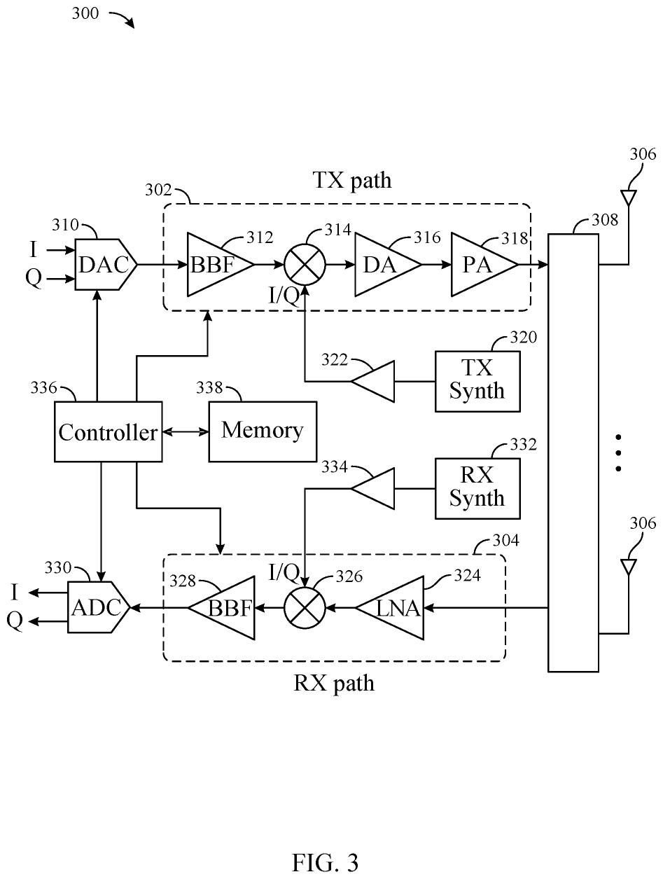

FIG. 3 is a block diagram of an example radio frequency (RF) transceiver circuit 300, in accordance with certain aspects of the present disclosure. The RF transceiver circuit 300 includes at least one transmit (TX) path 302 (also known as a “transmit chain”) for transmitting signals via one or more antennas 306 and at least one receive (RX) path 304 (also known as a “receive chain”) for receiving signals via the antennas 306. When the TX path 302 and the RX path 304 share an antenna 306, the paths may be connected with the antenna via an interface 308, which may include any of various suitable RF devices, such as a switch, a duplexer, a diplexer, a multiplexer, and the like.

Receiving in-phase (I) and/or quadrature (Q) baseband analog signals from a digital-to-analog converter (DAC) 310, the TX path 302 may include a baseband filter (BBF) 312, a mixer 314, a driver amplifier (DA) 316, and a power amplifier (PA) 318. The BBF 312, the mixer 314, the DA 316, and the PA 318 may be included in a radio frequency integrated circuit (RFIC). For certain aspects, the PA 318 may be external to the RFIC.

For certain aspects, the DAC 310 may be implemented by any of various suitable high-speed DAC topologies, such as a current-steering DAC. The BBF 312 filters the baseband signals received from the DAC 310, and the mixer 314 mixes the filtered baseband signals with a transmit local oscillator (LO) signal to convert the baseband signal of interest to a different frequency (e.g., upconvert from baseband to a radio frequency). This frequency-conversion process produces the sum and difference frequencies between the LO frequency and the frequencies of the baseband signal of interest. The sum and difference frequencies are referred to as the “beat frequencies.” The beat frequencies are typically in the RF range, such that the signals output by the mixer 314 are typically RF signals, which may be amplified by the DA 316 and/or by the PA 318 before transmission by the antenna(s) 306. While one mixer 314 is illustrated, several mixers may be used to upconvert the filtered baseband signals to one or more intermediate frequencies and to thereafter upconvert the intermediate frequency (IF) signals to a frequency for transmission.

The RX path 304 may include a low noise amplifier (LNA) 324, a mixer 326, and a baseband filter (BBF) 328. The LNA 324, the mixer 326, and the BBF 328 may be included in one or more RFICs, which may or may not be the same RFIC that includes the TX path components. RF signals received via the antenna(s) 306 may be amplified by the LNA 324, and the mixer 326 mixes the amplified RF signals with a receive local oscillator (LO) signal to convert the RF signal of interest to a different baseband frequency (e.g., downconvert). The baseband signals output by the mixer 326 may be filtered by the BBF 328 before being converted by an analog-to-digital converter (ADC) 330 to digital I and/or Q signals for digital signal processing.

Certain transceivers may employ frequency synthesizers with a variable-frequency oscillator (e.g., a voltage-controlled oscillator (VCO) or a digitally controlled oscillator (DCO)) to generate a stable, tunable LO with a particular tuning range. Thus, the transmit LO may be produced by a TX frequency synthesizer 320, which may be buffered or amplified by amplifier 322 before being mixed with the baseband signals in the mixer 314. Similarly, the receive LO may be produced by an RX frequency synthesizer 332, which may be buffered or amplified by amplifier 334 before being mixed with the RF signals in the mixer 326. For certain aspects, a single frequency synthesizer may be used for both the TX path 302 and the RX path 304. In certain aspects, the TX frequency synthesizer 320 and/or RX frequency synthesizer 332 may include a frequency multiplier, such as a frequency doubler, that is driven by an oscillator (e.g., a VCO) in the frequency synthesizer.

A controller 336 (e.g., controller/processor 280 in FIG. 2) may direct the operation of the RF transceiver circuit 300, such as transmitting signals via the TX path 302 and/or receiving signals via the RX path 304. The controller 336 may be a processor, a digital signal processor (DSP), an application-specific integrated circuit (ASIC), a field-programmable gate array (FPGA) or other programmable logic device (PLD), discrete gate or transistor logic, discrete hardware components, or any combination thereof. A memory 338 (e.g., memory 282 in FIG. 2) may store data and/or program codes for operating the RF transceiver circuit 300. The controller 336 and/or the memory 338 may include control logic (e.g., complementary metal-oxide-semiconductor (CMOS) logic).

While FIGS. 1, 2, and 3 provide a wireless communication network and components as an example application in which certain aspects of the present disclosure may be implemented to facilitate understanding, certain aspects described herein may be used in any of various other suitable systems.

### Example Transmitter With Predistortion

Wireless communication devices may use digital predistortion (DPD) processing to mitigate nonlinearities of the devices. For example, DPD processing may be used to effectively linearize the nonlinearity of a power amplifier in some transmission devices. DPD works by sensing the nonlinearity at the output of the power amplifier and feeding this back to DPD logic, which generates the reverse nonlinearity in the digital domain. This reverse nonlinearity is applied to the digital input signal, thereby effectively cancelling, or at least reducing, the nonlinearity effects of the power amplifier in the transmission device.

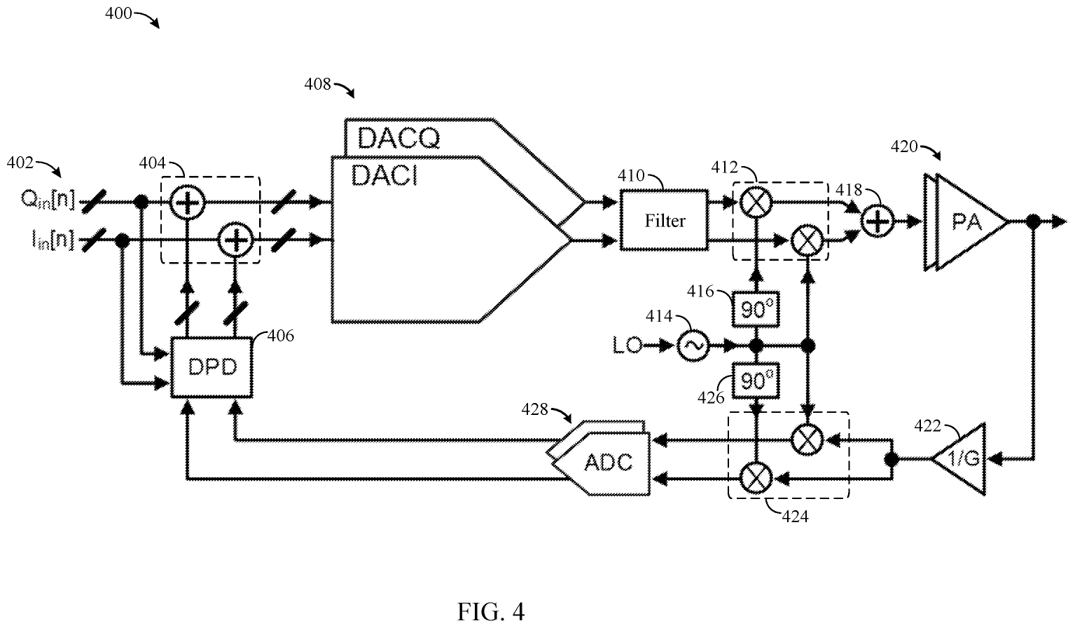

FIG. 4 is a block diagram of an example transmitter 400. The transmitter 400 may be a portion of a transceiver for certain aspects, and may have components similar to some components in the RF transceiver circuit 300.

The transmitter 400 may include a combiner stage 404 configured to combine in-phase (I) and quadrature (Q) digital input signals 402 (labeled “Iᵢₙ[n]” and “Qᵢₙ[n]”) with output signals from digital predistortion (DPD) logic 406. As such, the combiner stage 404 may include two combiners, as illustrated in FIG. 4. The digital input signals 402 may each be represented by a number (n) of bits (e.g., n=14 bits), and the output signals from the DPD logic 406 may each be represented by a number (m) of bits (e.g., m=9 bits).

The transmitter 400 may also include a DAC stage 408 (which may be analogous to the DAC 310 of FIG. 3). As shown, the DAC stage 408 may include at least one quadrature DAC (labeled “DACQ”) for converting the combined quadrature digital signal from the combiner stage 404 to a quadrature analog signal, and at least one in-phase DAC (labeled “DACI”) for converting the combined in-phase digital signal from the combiner stage 404 to an in-phase analog signal. As such, the DAC stage 408 may have inputs coupled to outputs of the combiner stage 404.

The transmitter 400 may also include a filter stage 410 (which may be analogous to the BBF 312 of FIG. 3) having inputs coupled to outputs of the DAC stage 408. The filter stage 410 may include at least one filter for the in-phase analog signal and at least one filter for the quadrature analog signal. A filter in the filter stage 410 may be any suitable type of filter, such as a baseband filter (BBF) or an intermediate frequency (IF) filter.

The transmitter 400 may also include a mixer stage 412 (which may be analogous to the mixer 314 of FIG. 3) to generate I/Q radio frequency (RF) signals. The mixer stage 412 may include an in-phase mixer and a quadrature mixer, as illustrated in FIG. 4. I/Q local oscillator (LO) inputs for the mixer stage 412 may be generated at an output of a frequency synthesizer 414 (which may be analogous to the TX frequency synthesizer 320 of FIG. 3) based on a control signal (labeled “LO”). An in-phase LO for the mixer 412 may be an unshifted version of the output of the frequency synthesizer 414, and quadrature LO for the mixer stage 412 may be a phase-shifted version of the output of the frequency synthesizer 414, shifted by 90° using a phase shifter 416.

The transmitter 400 may also include a combiner 418 to combine the in-phase and quadrature RF signals from the mixer stage 412. The combiner 418 may have an input coupled to outputs of the mixer stage 412, and an output coupled to an input of a power amplifier 420 (labeled “PA”), which may be analogous to the PA 318 of FIG. 3. The power amplifier 420 may be configured to amplify the combined RF signal at the output of the combiner 418 (e.g., for transmission of the signal by one or more antennas).

In some aspects, as shown, the transmitter 400 may also include a feedback receive path including an attenuator 422, another mixer stage 424, and an analog-to-digital converter (ADC) stage 428. Although not shown, the feedback receive path may also include one or more filter stages.

The attenuator 422 may have an input (selectively) coupled to an output of the power amplifier 420, and may be configured to reduce the amplitude of the signal from the output of the power amplifier 420 by a factor of 1/G. The mixer stage 424 may have I/Q LO inputs from the output of the frequency synthesizer 414. An in-phase LO for the in-phase mixer of the mixer stage 424 may be an unshifted version of the output of the frequency synthesizer 414, and a quadrature LO for the quadrature mixer of the mixer stage 424 may be a phase-shifted version of the output of the frequency synthesizer 414, shifted by 90° using a phase shifter 426. The ADC stage 428 may have inputs coupled to outputs of the mixer stage 424, and outputs coupled to feedback inputs of the DPD logic 406. The ADC stage 428 may be configured to convert the attenuated and downconverted RF signal from the output of the power amplifier 420 to digital I/Q signals.

The DPD logic 406 may effectively adjust the in-phase and quadrature digital input signals 402 to counteract, or at least reduce, the nonlinearity of the power amplifier 420. This may enable the transmitter 400 to push the power amplifier 420 closer to saturation and improve efficiency of the transmitter 400. The DPD logic 406 generally operates by generating a reverse nonlinearity of the power amplifier 420 and applying this reverse nonlinearity as predistortion signals to be combined with the digital input signals 402 by the combiner stage 404, thereby cancelling, or at least reducing, the nonlinearity. Depending on power amplifier types and power levels, the DPD logic 406 may be implemented with different DPD algorithms and architectures.

The nonlinear operations in the DPD logic 406 expand the bandwidth of the combined signals by 3-5 times compared to a bandwidth of the digital input signals 402 (also referred to as “main signals”) themselves. Because the predistortion signals should propagate to the power amplifier 420 with low droop and high dynamic range, the bandwidth of other components (e.g., the DACs in the DAC stage 408) in the transmitter 400 should be designed to cover the wider bandwidth of the predistortion signal(s) in addition to the bandwidth of the main signal(s).

However, the increased bandwidth specification may create problems in the other components in the transmitter 400. For example, the increased bandwidth specification may create a lower limit on the sampling rate of the DACs in the DAC stage 408 and/or other processing components in the transmit path. This may increase power consumption of the transmitter 400 (e.g., due to the use of high digital voltages to support high sampling rate operations).

Accordingly, in an effort to reduce the power consumption in such devices, certain aspects of the present disclosure are directed to a wireless transmission device with DPD capabilities, in which a main signal path and a predistortion signal path have been separated to route a main signal through a main DAC and to route a predistortion signal through a predistortion DAC.

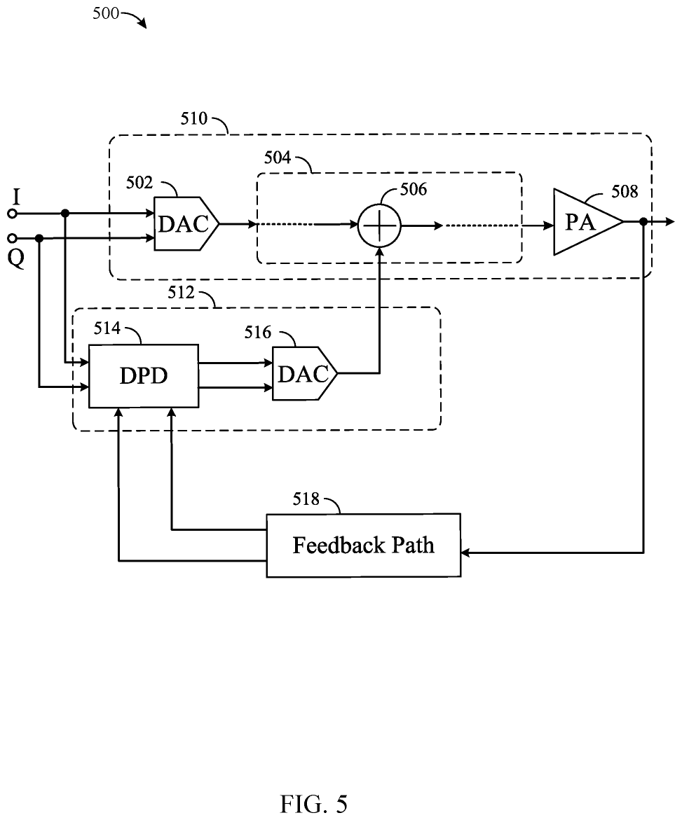

FIG. 5 is block diagram of an example transmitter 500, in accordance with certain aspects of the present disclosure. The transmitter 500 may be similar to the transmitter 400, but with a main signal path 510 and a separate predistortion signal path 512, where the predistortion signal path has its own predistortion signal DAC.

As shown, the main signal path 510 generally includes a first DAC stage 502 (also referred to as a “main signal DAC stage”), a power amplifier 508, and a combiner stage 506. In certain aspects, the power amplifier 508 may be similar to the power amplifier 420 in FIG. 4. According to certain aspects, the combiner stage 506 may be disposed in the main signal path 510 between an output of the first DAC stage 502 and an input of the power amplifier 508.

According to certain aspects, the main signal path 510 may further include a transmit chain 504 coupled between the output of the first DAC stage 502 and the input of the power amplifier 508. For certain aspects, the combiner stage 506 may be disposed in the main signal path 510 between the output of the first DAC stage 502 and the input to the transmit chain 504. In certain other aspects, such as the one illustrated in FIG. 5, the combiner stage 506 may be disposed in the transmit chain 504.

The predistortion signal path 512 may include DPD logic 514 and a second DAC stage 516 (also referred to as a “predistortion signal DAC stage” or a “supplemental DAC stage”). In certain aspects, the DPD logic 514 may be similar to the DPD logic 406 in FIG. 4. For certain aspects, an input of the first DAC stage 502 may be coupled to an input of the DPD logic 514, and an output of the DPD logic 514 may be coupled to an input of the second DAC stage 516. According to certain aspects, the transmitter 500 may also include a feedback path 518 configured to feed an output of the power amplifier 508 back to a feedback input of the DPD logic 514. The DPD logic 514 may be configured to adjust for nonlinearity of the power amplifier 508.

The combiner stage 506 may be configured to combine a predistortion signal in the predistortion signal path 512 with a main signal in the main signal path 510 after the main signal and the predistortion signal have passed through separate DACs (e.g., the first DAC stage 502 and the second DAC stage 516, respectively). That is, the combiner stage 506 may combine an analog main signal (or a processed version of the analog main signal) with an analog predistortion signal (or a processed version of the analog predistortion signal), to create an analog combined signal. As used herein, a “processed version” of an analog signal generally relates to an analog signal that has undergone additional signal processing, such as being filtered, upconverted, downconverted, amplified, attenuated, phase-shifted, etc.

By separating the main signal from the predistortion signal during digital-to-analog conversion, the power consumption of the transmitter 500 (and more specifically, of the first DAC stage 502 compared to the DAC stage 408) may be reduced, as discussed in more detail below.

The implementations described below may be similar to the transmitter 400, but with the main signal path 510 having a first DAC stage 502 and the predistortion signal path 512 having a second DAC stage, where the analog main signal and the analog predistortion signal are combined after digital-to-analog conversion in their separate paths. Accordingly, an explanation of some components which have already been discussed above with respect to FIG. 4 may not be repeated below.

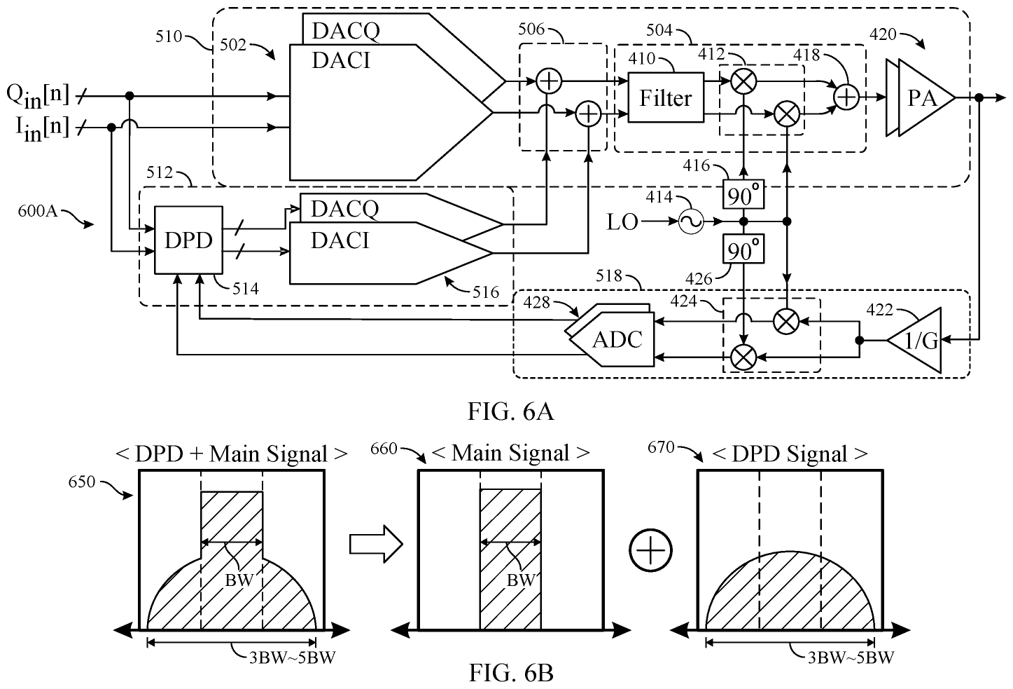

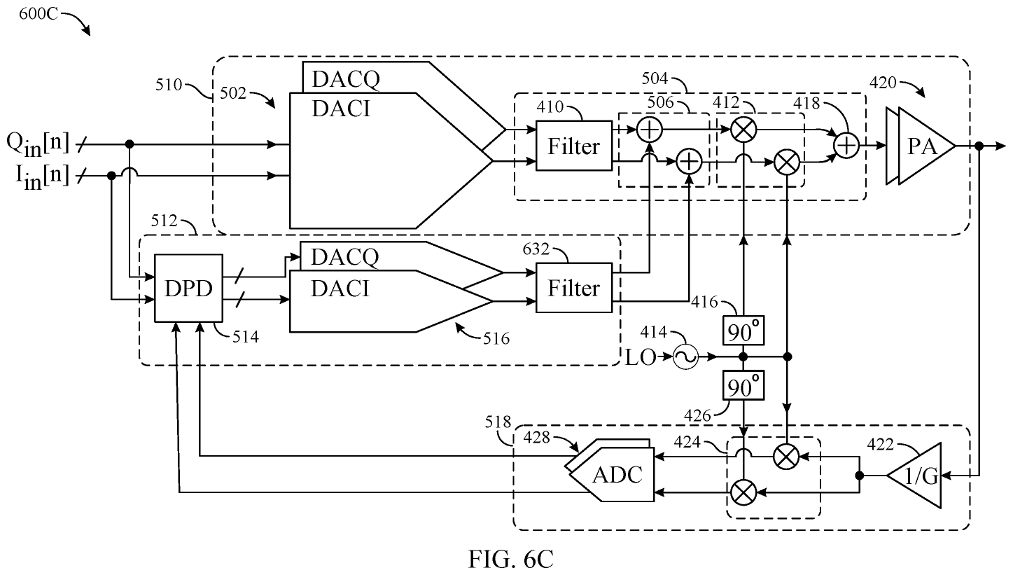

FIG. 6A is a block diagram of an example implementation 600A of the transmitter 500 of FIG. 5, in accordance with certain aspects of the present disclosure.

As shown, in some aspects, the first DAC stage 502 and the second DAC stage 516 may each comprise a plurality of DACs. For example, the first DAC stage 502 and the second DAC stage 516 may each include at least one DAC for converting a quadrature digital input signal (labeled “DACQ”) and at least one DAC for converting an in-phase digital input signal (labeled “DACI”). In some aspects, a DAC in the first DAC stage 502 may be the same DAC type (e.g., have the same DAC architecture or topology) as a DAC in the second DAC stage 516. For example, the DAC in the first DAC stage 502 and the DAC in the second DAC stage 516 may be current-steering DACs.

FIG. 6B conceptually illustrates splitting the frequency spectrum of a combined signal into a main signal and a predistortion signal, in accordance with certain aspects of the present disclosure. The x-axis of each graph represents frequency, and the y-axis of each graph represents a signal power level.

Graph 650 illustrates an example combined signal spectrum, which illustrates the bandwidth (labeled “BW”) of the main portion of the combined signal and the wider bandwidth (labeled “3BW˜5BW”) of the predistortion portion of the combined signal. This combined signal spectrum in graph 650 is an example of the high bandwidth and high dynamic range signal the DAC stage 408 should be designed to handle. According to aspects of the present disclosure, however, the combined signal represented by graph 650 may be split into two signals, namely, the main signal represented by the spectrum in graph 660 and the predistortion signal (e.g., DPD signal) represented by the spectrum in graph 670. Therefore, the main DAC in the main signal path can be designed to handle the higher power, higher dynamic range, and narrower bandwidth of the main signal in graph 660, whereas the supplemental DAC in the predistortion signal path can be designed (e.g., with lower resolution than the main DAC, but higher operating frequency) to handle the lower power, lower dynamic range, and wider bandwidth signal in graph 670.

In the implementation 600A, the main signal may propagate along the main signal path 510 and the predistortion signal may propagate along the predistortion signal path 512. That is, the main signal may be converted from a digital signal to an analog signal by the first DAC stage 502, and the predistortion signal may be converted from a digital signal to an analog signal by the second DAC stage 516. The combiner stage 506 may then combine analog versions of the main signal and the predistortion signal.

As illustrated in the graph 670, the predistortion signal has a bandwidth that is approximately 3-5 times wider than a bandwidth of the main signal (labeled “BW”). Accordingly, the second DAC stage 516 may be configured to have a wider bandwidth than the first DAC stage 502, to allow the second DAC stage 516 to process the predistortion signal. For example, in some aspects, a bandwidth of the second DAC stage 516 may be 3-5 times wider than a bandwidth of the first DAC stage 502.

On the other hand, because the bandwidth of the main signal is smaller than the bandwidth of the combined signals, the first DAC stage 502 may be configured with a reduced operating frequency (e.g., a reduced sampling frequency or sampling rate, compared to an operating frequency used in processing the combined signal).

Additionally, as illustrated in the graph 670, the power level of the predistortion signal is considerably less than the power level of the main signal. For example, the peak power level of the predistortion signal may be approximately 20 dBm/MHz less than the peak power level of the main signal. Accordingly, in some aspects, the second DAC stage 516 may be configured to have a lower operating power than the first DAC stage 502. The second DAC stage 516 may also be configured to have a lower resolution than the first DAC stage 502. For example, a DAC in the first DAC stage 502 may be a 12-bit DAC, whereas a DAC in the second DAC stage 516 may be a 6-bit DAC. In some aspects, the second DAC stage 516 may be configured to use a lower full-scale current than the first DAC stage 502. Because the second DAC stage 516 has reduced performance specifications (e.g., lower resolution), the second DAC stage 516 may be implemented by one or more smaller DACs, thereby reducing area consumption (e.g., a footprint of the transmitter circuit).

Additionally, the number of bits output by the DPD logic 514 may be reduced, which may reduce the power consumption of the DPD logic 514. For example, because the DAC stage 408 is configured to convert a high-bandwidth signal, the DPD logic 406 in FIG. 4 may perform a large number of digital arithmetic operations in order to output a high-resolution predistortion signal so as not to corrupt the main signal during digital-to-analog conversion. The digital arithmetic operations contribute to power consumption by the DPD logic 406. However, because the second DAC stage 516 may be configured to process signals with a lower power level (e.g., a lower dynamic range), the DPD logic 514 may output fewer bits. Accordingly, the DPD logic 514 may consume less power and/or have a smaller footprint than the DPD logic 406.

As shown, the transmit chain 504 may be coupled between the output of the first DAC stage 502 and the input of the power amplifier 508. In certain aspects, the transmit chain 504 may include a filter, a mixer, and a combiner, such as the BBF 312, the mixer 314, and the DA 316 of FIG. 3 or the filter stage 410, the mixer stage 412, and the combiner 418 of FIG. 4. In some aspects, the feedback path 518 may include an attenuator, a mixer, and an ADC, such as, for example, the attenuator 422, the mixer stage 424, and the ADC stage 428 of FIG. 4.

In the example implementation 600A, the combiner stage 506 is disposed in the main signal path 510 between the outputs of the first DAC stage 502 and the transmit chain 504. In this case, the combiner stage 506 may be coupled between the outputs of the first DAC stage 502 and the inputs of the filter stage 410, and the combiner stage 506 may be configured to combine the analog I/Q main signals at the outputs of the first DAC stage 502 with the analog I/Q predistortion signals at the outputs of the second DAC stage 516.

FIG. 6C is a block diagram of another example implementation 600C of the transmitter 500 of FIG. 5, in accordance with certain aspects of the present disclosure. The implementation 600C may be similar to the implementation 600A, but with the combiner stage 506 having a first set of inputs coupled to the outputs (as opposed to the inputs) of the filter stage 410. The implementation 600C may also include an additional filter stage 632 in the predistortion signal path 512. In this case, the combiner stage 506 may have a second set of inputs coupled to outputs of the filter stage 632 and may be configured to combine filtered (e.g., processed) versions of the analog main signals and of the analog predistortion signals. Additionally, in this case, the filter stage 410 may include narrowband filters to filter out noise outside of the bandwidth of the main signals, and the filter stage 632 may have filters with wider bandwidths (e.g., wideband filters).

Although not illustrated, a person of ordinary skill in the relevant art will appreciate that, in yet another implementation, the combiner stage 506 may be coupled between outputs of the mixer stage 412 and an input of the power amplifier 508. In this case, the predistortion signal path 512 may also include another mixer stage having inputs coupled to outputs of the filter stage 632, and outputs of this other mixer stage may be coupled to inputs of the combiner stage 506 from the predistortion signal path 512.

Aspects of the present disclosure may offer reduced power consumption compared to some other transmitter architectures. The reduced power consumption may also reduce the overall heat generated by the transmitter, thereby allowing thermal design relaxation.

### Example Operations for Wireless Communication

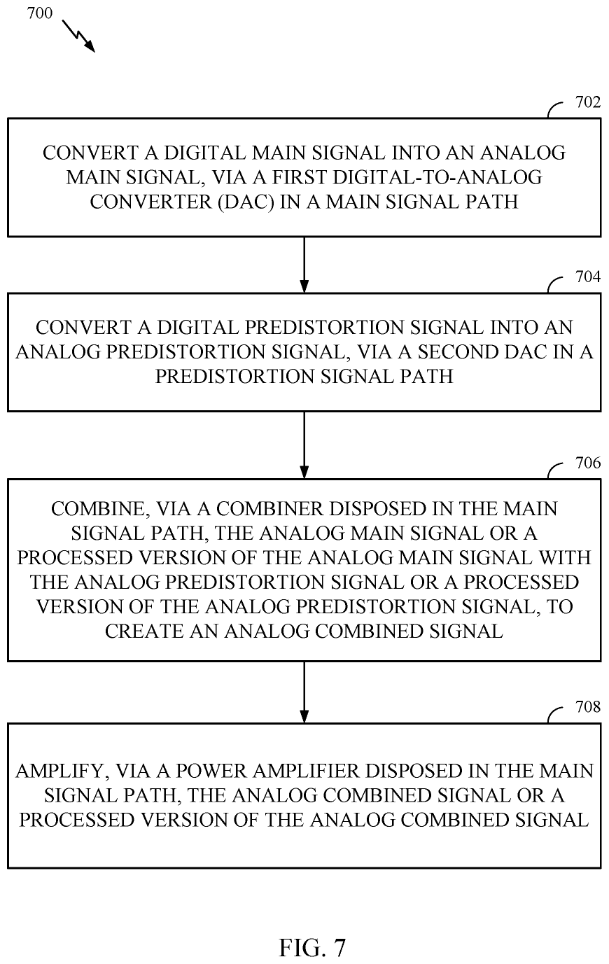

FIG. 7 is a flow diagram of example operations 700 for wireless communication, in accordance with certain aspects of the present disclosure. The operations 700 may be performed, for example, by a transmitter with digital predistortion (DPD) processing capabilities (e.g., the transmitter 500, or the implementations 600A or 600C).

The operations 700 may begin, at block 702, by converting a digital main signal into an analog main signal, via a first digital-to-analog converter (DAC) (e.g., a DAC in the first DAC stage 502) in a main signal path (e.g., the main signal path 510). The operations 700 may also involve, at block 704, converting a digital predistortion signal into an analog predistortion signal, via a second DAC (e.g., a DAC in the second DAC stage 516) in a predistortion signal path (e.g., the predistortion signal path 512). At block 706, the operations 700 may further involve combining, via a combiner (e.g., a combiner in the combiner stage 506) disposed in the main signal path, the analog main signal or a processed version of the analog main signal with the analog predistortion signal or a processed version of the analog predistortion signal, to create an analog combined signal. The operations 700 may further involve, at block 708, amplifying, via a power amplifier (e.g., the power amplifier 508) disposed in the main signal path, the analog combined signal or a processed version of the analog combined signal.

According to certain aspects, the operations 700 further include filtering (e.g., with a filter in the filter stage 410) the analog main signal to generate a filtered version of the analog main signal and filtering (e.g., with a filter in the filter stage 632) the analog predistortion signal to generate a filtered version of the analog predistortion signal. In this case, the combining at block 706 may involve combining the filtered version of the analog main signal with the filtered version of the analog predistortion signal to create the analog combined signal.

According to certain aspects, the operations 700 further include filtering (e.g., with a filter in the filter stage 410) the analog main signal to generate a filtered version of the analog main signal; filtering (e.g., with a filter in the filter stage 632) the analog predistortion signal to generate a filtered version of the analog predistortion signal; upconverting (e.g., with a first mixer in the main signal path, such as a mixer in the mixer stage 412) the filtered version of the analog main signal to generate an upconverted version of the analog main signal; and upconverting (e.g., with a second mixer in the predistortion signal path) the filtered version of the analog predistortion signal to generate an upconverted version of the analog predistortion signal. In this case, the combining at block 706 may involve combining the upconverted version of the analog main signal with the upconverted version of the analog predistortion signal to create the analog combined signal.

According to certain aspects, the first DAC is a different DAC type than the second DAC. For other aspects, the first DAC is the same DAC type as the second DAC.

According to certain aspects, the second DAC has a wider bandwidth than the first DAC.

According to certain aspects, the second DAC has a lower operating power than the first DAC, has a higher sampling rate than the first DAC, has a lower resolution than the first DAC, and/or uses a lower full-scale current than the first DAC.

According to certain aspects, the operations 700 further include applying digital predistortion, with digital predistortion logic (e.g., DPD logic 514) in the predistortion signal path, to the digital main signal to generate the digital predistortion signal. For certain aspects, the applied digital predistortion is based on the amplified analog combined signal.

### Example Aspects

In addition to the various aspects described above, specific combinations of aspects are within the scope of the present disclosure, some of which are detailed below:
Aspect 1: An apparatus for wireless communication, comprising: a main signal path comprising a first digital-to-analog converter (DAC), a power amplifier, and a combiner, the combiner being disposed in the main signal path between an output of the first DAC and an input of the power amplifier; and a predistortion signal path comprising a second DAC, wherein the combiner is configured to combine a predistortion signal in the predistortion signal path with a main signal in the main signal path.
Aspect 2: The apparatus of Aspect 1, wherein the main signal path further comprises a transmit chain coupled between the output of the first DAC and the input of the power amplifier and wherein the combiner is disposed in the main signal path between the output of the first DAC and the transmit chain.
Aspect 3: The apparatus of Aspect 1, wherein the main signal path further comprises a transmit chain coupled between the output of the first DAC and the input of the power amplifier and wherein the combiner is disposed in the transmit chain.
Aspect 4: The apparatus of Aspect 3, wherein the transmit chain comprises a filter and wherein an input of the combiner is coupled to an output of the filter.
Aspect 5: The apparatus of Aspect 3 or 4, wherein the transmit chain comprises a mixer and wherein an input of the combiner is coupled to an output of the mixer.
Aspect 6: The apparatus of any of the preceding Aspects, wherein the first DAC is a same DAC type as the second DAC.
Aspect 7: The apparatus of Aspect 6, wherein the first DAC and the second DAC comprise current-steering DACs.
Aspect 8: The apparatus of any of the preceding Aspects, wherein the second DAC is configured to have a wider bandwidth than the first DAC.
Aspect 9: The apparatus of any of the preceding Aspects, wherein a bandwidth of the second DAC is 3-5 times wider than a bandwidth of the first DAC.
Aspect 10: The apparatus of any of the preceding Aspects, wherein the second DAC is configured to have at least one of: a lower operating power than the first DAC; a higher sampling rate than the first DAC; or a lower resolution than the first DAC.
Aspect 11: The apparatus of any of the preceding Aspects, wherein the second DAC is configured to use a lower full-scale current than the first DAC.
Aspect 12: The apparatus of any of the preceding Aspects, wherein the predistortion signal path further comprises digital predistortion (DPD) logic, wherein an input of the first DAC is coupled to an input of the DPD logic, wherein the DPD logic is configured to adjust for nonlinearity of the power amplifier, and wherein an output of the DPD logic is coupled to an input of the second DAC.
Aspect 13: A method of wireless communication, comprising: converting a digital main signal into an analog main signal, via a first digital-to-analog converter (DAC) in a main signal path; converting a digital predistortion signal into an analog predistortion signal, via a second DAC in a predistortion signal path; combining, via a combiner disposed in the main signal path, the analog main signal or a processed version of the analog main signal with the analog predistortion signal or a processed version of the analog predistortion signal, to create an analog combined signal; and amplifying, via a power amplifier disposed in the main signal path, the analog combined signal or a processed version of the analog combined signal.
Aspect 14: The method of Aspect 13, further comprising: filtering the analog main signal to generate a filtered version of the analog main signal; and filtering the analog predistortion signal to generate a filtered version of the analog predistortion signal, wherein the combining comprises combining the filtered version of the analog main signal with the filtered version of the analog predistortion signal to create the analog combined signal.
Aspect 15: The method of Aspect 13, further comprising: filtering the analog main signal to generate a filtered version of the analog main signal; filtering the analog predistortion signal to generate a filtered version of the analog predistortion signal; upconverting the filtered version of the analog main signal to generate an upconverted version of the analog main signal; and upconverting the filtered version of the analog predistortion signal to generate an upconverted version of the analog predistortion signal, wherein the combining comprises combining the upconverted version of the analog main signal with the upconverted version of the analog predistortion signal to create the analog combined signal.
Aspect 16: The method of any of Aspects 13-15, wherein the first DAC is a different DAC type than the second DAC.
Aspect 17: The method of any of Aspects 13-16, wherein the second DAC has a wider bandwidth than the first DAC.
Aspect 18: The method of any of Aspects 13-17, wherein the second DAC has at least one of: a lower operating power than the first DAC; a higher sampling rate than the first DAC; or a lower resolution than the first DAC.
Aspect 19: The method of any of Aspects 13-18, further comprising applying digital predistortion, with digital predistortion logic in the predistortion signal path, to the digital main signal to generate the digital predistortion signal, wherein the applied digital predistortion is based on the amplified analog combined signal.
Aspect 20: An apparatus for wireless communication, comprising: first means for converting a digital main signal into an analog main signal, the first means for converting being disposed in a main signal path; second means for converting a digital predistortion signal into an analog predistortion signal, the second means for converting being disposed in a predistortion signal path; means for combining the analog main signal or a processed version of the analog main signal with the analog predistortion signal or a processed version of the analog predistortion signal, to create an analog combined signal, the means for combining being disposed in the main signal path; and means for amplifying the analog combined signal or a processed version of the analog combined signal, the means for amplifying being disposed in the main signal path.

### Conclusion

Described herein are architectures to address increased power consumption in transmitters with digital predistortion (DPD) processing. Certain aspects of the present disclosure provide techniques and circuitry for wireless communication using a transmitter capable of DPD and having a main signal path separated from a DPD signal path, each path including a distinct digital-to-analog converter (DAC). By separating the signal paths, the operating characteristics of the respective DACs used to process the signals may be designed so that each DAC may process its respective signal more efficiently and with better overall performance and lower power consumption and real estate, compared to a single DAC processing a combination of the main and DPD signals.

The above description provides examples, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method which is practiced using other structure, functionality, or structure and functionality in addition to, or other than, the various aspects of the disclosure set forth herein. It should be understood that any aspect of the disclosure disclosed herein may be embodied by one or more elements of a claim.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components. For example, means for converting a digital main signal into an analog main signal may include a DAC, such as a DAC (e.g., DACI or DACQ) in the first DAC stage 502 of FIG. 5, 6A, or 6C. As another example, means for converting a digital predistortion signal into an analog predistortion signal may include a DAC, such as a DAC (e.g., DACI or DACQ) in the second DAC stage 516 of FIG. 5, 6A, or 6C. Means for combining may include a combiner, such as the combiner stage 506 of FIG. 5, 6A, or 6C; and means for amplifying may include an amplifier, such as the power amplifier 508 of FIG. 5, 6A, or 6C.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

1. An apparatus for wireless communication, comprising:
a main signal path comprising a first digital-to-analog converter (DAC), a power amplifier, and a combiner, the combiner being disposed in the main signal path between an output of the first DAC and an input of the power amplifier; and
a predistortion signal path comprising a second DAC, wherein the combiner is configured to combine a predistortion signal in the predistortion signal path with a main signal in the main signal path.

2. The apparatus of claim 1, wherein the main signal path further comprises a transmit chain coupled between the output of the first DAC and the input of the power amplifier and wherein the combiner is disposed in the main signal path between the output of the first DAC and the transmit chain.

3. The apparatus of claim 1, wherein the main signal path further comprises a transmit chain coupled between the output of the first DAC and the input of the power amplifier and wherein the combiner is disposed in the transmit chain.

4. The apparatus of claim 3, wherein the transmit chain comprises a filter and wherein an input of the combiner is coupled to an output of the filter.

5. The apparatus of claim 3, wherein the transmit chain comprises a mixer and wherein an input of the combiner is coupled to an output of the mixer.

6. The apparatus of claim 1, wherein the first DAC is a same DAC type as the second DAC.

7. The apparatus of claim 6, wherein the first DAC and the second DAC comprise current-steering DACs.

8. The apparatus of claim 1, wherein the second DAC is configured to have a wider bandwidth than the first DAC.

9. The apparatus of claim 8, wherein a bandwidth of the second DAC is 3-5 times wider than a bandwidth of the first DAC.

10. The apparatus of claim 1, wherein the second DAC is configured to have at least one of:
a lower operating power than the first DAC;
a higher sampling rate than the first DAC; or
a lower resolution than the first DAC.

11. The apparatus of claim 1, wherein the second DAC is configured to use a lower full-scale current than the first DAC.

12. The apparatus of claim 1, wherein the predistortion signal path further comprises digital predistortion (DPD) logic, wherein an input of the first DAC is coupled to an input of the DPD logic, wherein the DPD logic is configured to adjust for nonlinearity of the power amplifier, and wherein an output of the DPD logic is coupled to an input of the second DAC.

13. A method of wireless communication, comprising:
converting a digital main signal into an analog main signal, via a first digital-to-analog converter (DAC) in a main signal path;
converting a digital predistortion signal into an analog predistortion signal, via a second DAC in a predistortion signal path;
combining, via a combiner disposed in the main signal path, the analog main signal or a processed version of the analog main signal with the analog predistortion signal or a processed version of the analog predistortion signal, to create an analog combined signal; and
amplifying, via a power amplifier disposed in the main signal path, the analog combined signal or a processed version of the analog combined signal.

14. The method of claim 13, further comprising:
filtering the analog main signal to generate a filtered version of the analog main signal; and
filtering the analog predistortion signal to generate a filtered version of the analog predistortion signal, wherein the combining comprises combining the filtered version of the analog main signal with the filtered version of the analog predistortion signal to create the analog combined signal.

15. The method of claim 13, further comprising:
filtering the analog main signal to generate a filtered version of the analog main signal;
filtering the analog predistortion signal to generate a filtered version of the analog predistortion signal;
upconverting the filtered version of the analog main signal to generate an upconverted version of the analog main signal; and
upconverting the filtered version of the analog predistortion signal to generate an upconverted version of the analog predistortion signal, wherein the combining comprises combining the upconverted version of the analog main signal with the upconverted version of the analog predistortion signal to create the analog combined signal.

16. The method of claim 13, wherein the first DAC is a different DAC type than the second DAC.

17. The method of claim 13, wherein the second DAC has a wider bandwidth than the first DAC.

18. The method of claim 13, wherein the second DAC has at least one of:
a lower operating power than the first DAC;
a higher sampling rate than the first DAC; or
a lower resolution than the first DAC.

19. The method of claim 13, further comprising applying digital predistortion, with digital predistortion logic in the predistortion signal path, to the digital main signal to generate the digital predistortion signal, wherein the applied digital predistortion is based on the amplified analog combined signal.

20. An apparatus for wireless communication, comprising:
first means for converting a digital main signal into an analog main signal, the first means for converting being disposed in a main signal path;
second means for converting a digital predistortion signal into an analog predistortion signal, the second means for converting being disposed in a predistortion signal path;
means for combining the analog main signal or a processed version of the analog main signal with the analog predistortion signal or a processed version of the analog predistortion signal, to create an analog combined signal, the means for combining being disposed in the main signal path; and
means for amplifying the analog combined signal or a processed version of the analog combined signal, the means for amplifying being disposed in the main signal path.
